(19) United States
(12) Patent Application Publication
(10) Pub. No.: US 2019/0080812 A1
(43) Pub. Date: Mar. 14, 2019

(54) ULTRAVIOLET RADIATION APPARATUS

(71) Applicant: Shenzhen China Star Optoelectronics Semiconductor Display Technology Co., Ltd., Shenzhen, Guangdong (CN)

(72) Inventor: Ting SHI, Shenzhen, Guangdong (CN)

(73) Assignee: SHENZHEN CHINA STAR OPTOELECTRONICS SEMICONDUCTOR TECHNOLOGY CO., LTD., Shenzhen, Guangdong (CN)

(21) Appl. No.: 15/577,026

(22) PCT Filed: Nov. 9, 2017
(86) PCT No.: PCT/CN2017/110194

§ 371 Date: Nov. 27, 2017

(30) Foreign Application Priority Data
Sep. 12, 2017 (CN) 201710816121.7

(51) Int. Cl. G21K 5/00; B08B 7/00; H01L 21/67

(52) U.S. Cl. CPC G21K 5/00; H01L 21/67115; B08B 7/0057

(57) ABSTRACT

The present disclosure provides an ultraviolet (UV) radiation apparatus, where the UV radiation apparatus includes a chamber containing substrates, a sample stage supporting the substrates, UV lamps emitting UV light arranged opposite to the sample stage, and a mirror reflective structure arranged in the chamber. The sample stage is positioned at a top of the chamber or a bottom of the chamber. The mirror reflective structure includes protrusions or recesses that are orderly arranged; the protrusions or the recesses reflect the UV light along all directions and the UV light is irradiated on the mirror reflective structure.

### BACKGROUND OF INVENTION

### 1. Field of Invention

The present disclosure relates to the field of ultraviolet lights, and more particularly to an ultraviolet radiation apparatus.

### 2. Description of Prior Art

UV light cleaning technology uses photosensitive oxidation of organic compounds to remove organic substances adhered to material surfaces. The UV radiation apparatus performs cleaning operations using UV lights for atomic cleanliness of the material surfaces. In LCDs and OLEDs production, photoresists, PI adhesives, directional films, chromium films, and color films, before coating, are required to be subjected to light cleaning, further greatly improving wettability and adhesive force of surfaces of substrates. Density of the large scale integrated circuit gets higher, lattice refinement gets denser, and cleanliness of the surfaces of the substrates increases. In semiconductor production, silicon wafers are coated with a protective film and an aluminum evaporation film, which are subjected to light cleaning, further improving adhesion forces, and keeping pinholes and cracks from occurring. After the optical glass is cleaned by the UV light, film coating quality is improved.

In addition, the UV light is used for radiation curing. The radiation curing uses electromagnetic radiation (such as UV or an electron beam irradiates coating layer) to generate radio polymerization and radiation crosslinking. Chemical processes rapidly convert low-molecular-weight substances into high-molecular-weight product, and no solvent or an extremely small amount of solvent is contained. After irradiation, liquid film is almost 100% cured so that emission of volatile organic compounds (VOC) is very low.

Prior art UV radiation apparatuses have an issue that ultraviolet irradiation is not uniform, because ultraviolet lights are unevenly distributed in a chamber, further affecting ultraviolet cleaning performance and ultraviolet radiation curing, and which causes obvious issues in larger production processes.

### SUMMARY OF THE INVENTION

The aim of the present disclosure is to provide an ultraviolet (UV) radiation apparatus capable of improving UV cleanliness or UV curing.

In order to solve the above issue, the present disclosure provides technical scheme as follows:

An ultraviolet (UV) radiation apparatus of the present disclosure comprises:
a chamber containing substrates;
a sample stage supporting the substrates, where the sample stage is positioned at a top of the chamber or a bottom of the chamber;
UV lamps emitting UV light, where the UV lamps are arranged opposite to the sample stage and are positioned at the top of the chamber or the bottom of the chamber;
a mirror reflective structure arranged in the chamber and reflecting the UV light emitted by the UV lamps.

The mirror reflective structure comprises protrusions or recesses that are orderly arranged. The UV light is irradiated on the mirror reflective structure and the protrusions or the recesses reflect the UV light along all directions. The mirror reflective structure is arranged in a predetermined position of the chamber. The predetermined position of the chamber at least comprises one of four surfaces, the top, and the bottom of the chamber.

According to a preferable embodiment of the present disclosure, the protrusions or the recesses are distributed in the entire mirror reflective structure.

According to a preferable embodiment of the present disclosure, the protrusions or the recesses are cone-shaped, pyramid-shaped, prismatic-shaped, tip-convex-shaped, or circular-convex-shaped.

According to a preferable embodiment of the present disclosure, surfaces of the protrusions or the recesses are mirror surfaces.

According to a preferable embodiment of the present disclosure, irradiating range of the UV lamps is greater than a region occupied by the sample stage.

According to a preferable embodiment of the present disclosure, the chamber comprises at least two sample stages, and the at least two sample stages are positioned at same side of the top of the chamber or the bottom of the chamber to support at least one substrate.

According to a preferable embodiment of the present disclosure, the UV radiation apparatus comprises at least two UV lamps, and the at least two UV lamps are symmetrically distributed at the top of the chamber.

According to a preferable embodiment of the present disclosure, the UV lamps are the UV lamp panel, and the UV lamp panel covers an entire top or an entire bottom of the chamber.

According to a preferable embodiment of the present disclosure, the sample stage that is raised or lowered to pick up and place the substrates.

The present disclosure further provides an ultraviolet (UV) radiation apparatus, where the UV radiation apparatus comprises:
a chamber containing substrates;
a sample stage supporting the substrates, where the sample stage is positioned at a top of the chamber or a bottom of the chamber;
UV lamps emitting UV light, where the UV lamps are arranged opposite to the sample stage and are positioned at the top of the chamber or the bottom of the chamber;
a mirror reflective structure arranged in the chamber and reflecting the UV light emitted by the UV lamps.

The mirror reflective structure comprises protrusions or recesses that are orderly arranged. The UV light is irradiated on the mirror reflective structure and the protrusions or the recesses reflect the UV light along all directions.

According to a preferable embodiment of the present disclosure, the protrusions or the recesses are distributed in entire mirror reflective structure.

According to a preferable embodiment of the present disclosure, the protrusions or the recesses are cone-shaped, pyramid-shaped, prismatic-shaped, tip-convex-shaped, or circular-convex-shaped.

According to a preferable embodiment of the present disclosure, surfaces of the protrusions or the recesses are mirror surfaces.

According to a preferable embodiment of the present disclosure, irradiating range of the UV light is greater than a region occupied by the sample stage.

According to a preferable embodiment of the present disclosure, the chamber comprises at least two sample stages, and the at least two sample stages are positioned at same side of the top of the chamber or the bottom of the chamber to support at least one substrate.

According to a preferable embodiment of the present disclosure, the UV radiation apparatus comprises at least two UV lamps, and the at least two UV lamps are symmetrically distributed at the top of the chamber.

According to a preferable embodiment of the present disclosure, the UV lamps are the UV lamp panel, and the UV lamp panel covers an entire top or an entire bottom of the chamber.

According to a preferable embodiment of the present disclosure, the sample stage that is raised or lowered to pick up and place the substrates.

Beneficial effects of the present disclosure are: compared with a UV radiation apparatus in prior art, the UV radiation apparatus of the present disclosure uses the mirror reflective structure to arrange on the four surfaces of the UV radiation apparatus, the UV light is irradiated on the mirror reflective structure and the protrusions or the recesses reflect the UV light along all directions, further improving irradiated uniformity of the UV light, effectively improving UV cleaning function or UV curing function, uniformity of UV cleaning or UV curing, and having obvious improvement in larger production processes.

### BRIEF DESCRIPTION OF THE DRAWINGS

In order to describe clearly the embodiment in the present disclosure or the prior art, the following will introduce the drawings for the embodiment shortly. Obviously, the following description is only a few embodiments, for the common technical personnel in the field it is easy to acquire some other drawings without creative work.

FIG. 1 is a schematic diagram of an ultraviolet radiation apparatus according a first embodiment of the present disclosure.

FIG. 2 is a schematic diagram of the ultraviolet radiation apparatus according a second embodiment of the present disclosure.

FIG. 3 is other structural diagram of a mirror reflective structure according a third embodiment of the present disclosure.

### DETAILED DESCRIPTION OF THE PREFERRED EMBODIMENTS

The following description of every embodiment with reference to the accompanying drawings is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure. In the drawings, components having similar structures are denoted by the same numerals.

The present disclosure can solve the technical issue that ultraviolet irradiation is not uniform, since ultraviolet lights is unevenly distributed in a chamber, further affecting ultraviolet cleaning performance and ultraviolet radiation curing. The embodiment of the present disclosure can overcome the above issues.

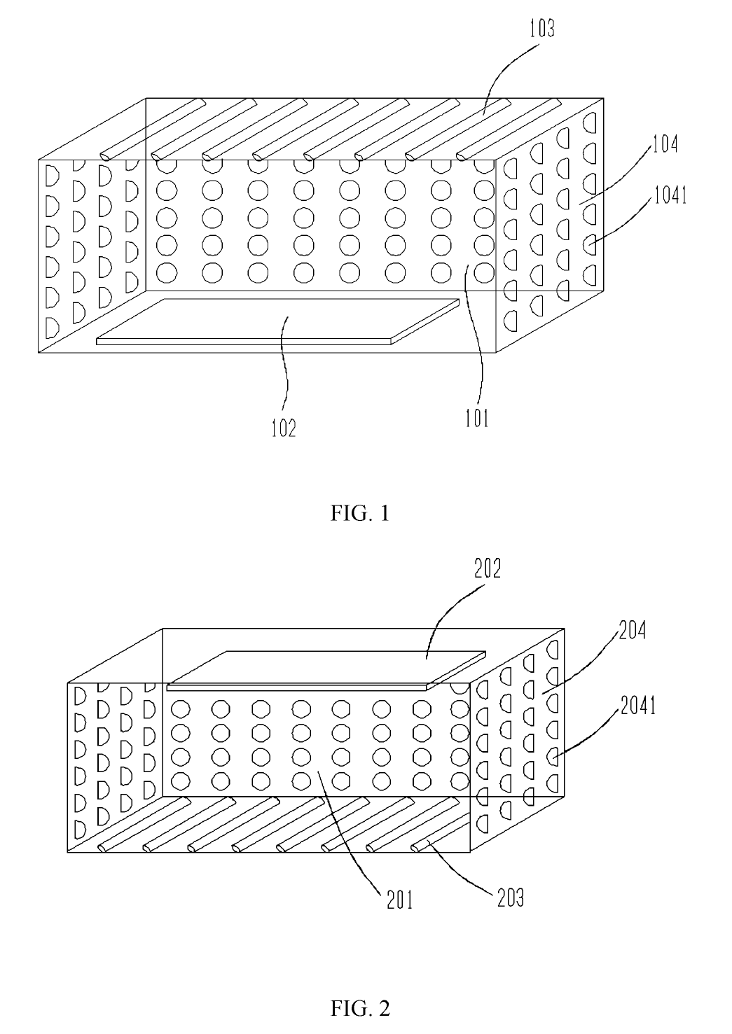

FIG. 1 is a schematic diagram of an ultraviolet (UV) radiation apparatus according a first embodiment of the present disclosure. The UV radiation apparatus comprises a chamber 101 containing substrates, a sample stage 102 supporting the substrates, UV lamps 103 emitting UV light, and a mirror reflective structure 104 reflecting the UV light emitted by the UV lamps 103. The sample stage 102 is positioned at a bottom of the chamber 101, and a gap between four surfaces of the sample stage 102 and the chamber 101. The UV lamps 103 are arranged opposite to the sample stage and are positioned at a top of the chamber. The UV radiation apparatus comprises at least two UV lamps 103, and the at least two UV lamps 103 are symmetrically distributed at the top of the chamber 101. Irradiating range of the UV lamps 103 is greater than a region occupied by the sample stage 102. The UV lamps 103 are the UV lamp panel, and the UV lamp panel covers an entire top of the chamber 101. The mirror reflective structure 104 comprises protrusions 1041 or recesses that are orderly arranged; the protrusions 1041 or the recesses reflect the UV light along all directions and the UV light is irradiated on the mirror reflective structure 104. The mirror reflective structure 104 is arranged in a predetermined position of the chamber 101. The predetermined position of the chamber 101 at least comprises one of four surfaces, the top and the bottom of the chamber 101. The protrusions 1041 or the recesses are distributed in entire mirror reflective structure 104. The protrusions 1041 or the recesses are cone-shaped, pyramid-shaped, prismatic-shaped, tip-convex-shaped, or circular-convex-shaped, and so on. The protrusions 1041 are semicircle-shaped, and surfaces of the protrusions 1041 are mirror surfaces.

The chamber 101 comprises at least two sample stages 102, and the at least two sample stages are positioned at same side of the bottom of the chamber 101 to support at least one substrate. The bottom of the sample stage 102 has an adjusting device that is raised or lowered to pick up and place the substrates. Champing grooves are arranged on the sample stage to fix the substrates. A number of the clamping grooves are set according to requirements to fix a plurality of the substrates. It should be understood that clamping portions are arranged on the sample stage 102 to clamp an upper end and a lower end of the substrates and fix the substrates. Upper clamping portions move along the sample stage 102, and lower the clamping portions and the upper clamping portions move opposite to each other in parallel. The lower clamping portions and the upper clamping portions move in a reciprocating motion, thus, the substrates can be in a certain angle with the sample stage 102, and a back face and a front face of the substrates can face the UV lamps 103 and can be irradiated by the UV lamps 103.

Material of the mirror reflective structure 104 has a high reflection performance, and the mirror reflective structure 104 can efficiently reflect the UV light to the chamber 101, further improving usable ratio of the lights. When the UV light is irradiated on surfaces of the protrusions 1041 or surfaces of the recesses, and the surfaces of the protrusions 1041 or the surfaces of the recesses are not on the same as surfaces of non-protrusion regions or non-recess regions of the mirror reflective structure 104 (or form a certain angle), the UV light is irradiated on the mirror reflective structure and the protrusions or the recesses reflect the UV light along all directions, further improving irradiated uniformity of the UV light in the chamber 101 and solving the issue that the UV irradiation is not uniform.

FIG. 2 is a schematic diagram of the UV radiation apparatus according a second embodiment of the present disclosure. The UV radiation apparatus comprises a chamber 201 containing substrates, a sample stage 202 supporting the substrates, UV lamps 203 emitting UV light, and a mirror reflective structure 204 reflecting the UV light emitted by the UV lamps 203. The sample stage 202 is positioned at a top of the chamber 201, and a gap between four surfaces of the sample stage 202 and the chamber 201. The UV lamps 203 are arranged opposite to the sample stage and are positioned at a bottom of the chamber 201. The UV radiation apparatus comprises at least two UV lamps 203, and the at least two UV lamps 203 are symmetrically distributed at the bottom of the chamber 201. Irradiating range of the UV lamps 203 is greater than a region occupied by the sample stage 202. The mirror reflective structure 204 reflects the UV light emitted by the UV lamps. The mirror reflective structure 204 comprises protrusions 2041 that are orderly arranged. It should be understood that the mirror reflective structure 204 comprises recesses. The UV light is irradiated on the mirror reflective structure 204 and the protrusions 2041 reflect the UV light along all directions to make the irradiated uniformity of the UV light in the chamber 201.

The substrates are in contact with the surface of the sample stage 202. Clamping slots or clamping buckles to fix the substrates. The sample stage 202 is the top of the chamber 201 to take and place the substrates.

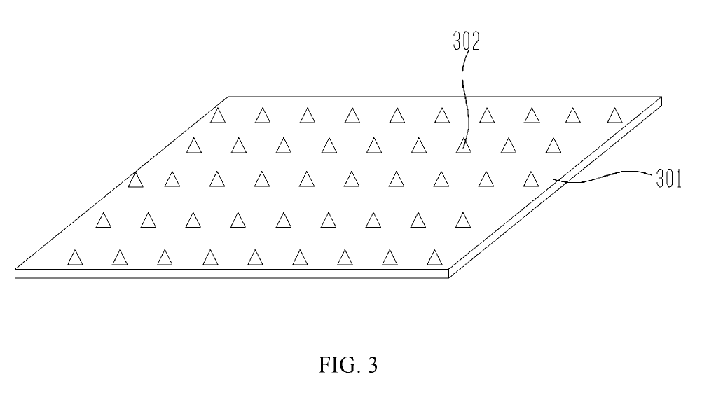

FIG. 3 is other structural diagram of a mirror reflective structure according a third embodiment of the present disclosure. The mirror reflective structure 301 comprises planar regions and non-planar regions, where the non-planar regions are regarded as protrusions 302 or recesses, and the protrusions 302 are distributed on surfaces of the mirror reflective structure 301 in array. Gaps are arranged between adjacent two protrusions 302. The gaps are the planar regions having a predetermined width. Each surface of the protrusions 302 can be in a certain angle with the planar regions. In the embodiment, the protrusions 302 are regarded as triangular pyramid and the surfaces of the protrusions are mirror surfaces, thus the UV light can be reflected to each direction. There are not limit to specific structure of the protrusions 302 or recesses, only the protrusions 302 or recesses can be in a certain angle with the planar regions to reflect the UV light along each direction.

Principle of the UV light cleaning technology is to use photosensitive oxidation of organic compound to remove organic substances adhered to material surfaces. The UV radiation apparatus perform cleaning operations using UV light, for atomic cleanliness of the material surfaces, and ensuring uniformity of cleanliness degree of the material surfaces. Distribution of the UV light in the UV radiation apparatus is relatively uniform, so that all angles of the substrates have uniform cleanliness. In LCDs and OLEDs production, photoresists, PI adhesives, directional films, chromium films, and color films, before coating, are required to be subjected to light cleaning. Thus, uniformity of the lights directly affects light cleaning. The UV radiation apparatus greatly increases cleanliness degree and saves cleaning time.

In addition, the UV radiation apparatus of the present disclosure is used to for radiation curing. The UV lights is irradiated on coating layer, part of the UV light reflects each direction through the mirror reflective structure arranged in the predetermined position of the UV radiation apparatus to improve irradiation uniformity of the UV light, further fast curing the coating layer and ensuring uniformity of the coating layer.

Compared with a UV radiation apparatus in prior art, the UV radiation apparatus of the present disclosure uses the mirror reflective structure to arrange on the four surfaces of the UV radiation apparatus, the UV light is irradiated on the mirror reflective structure and the protrusions or the recesses reflect the UV light along all directions, further improving irradiated uniformity of the UV light, effectively improving UV cleaning function or UV curing function, uniformity of UV cleaning or UV curing, and having obvious improvement in larger production processes.

It should be understood that the present disclosure has been described with reference to certain preferred and alternative embodiments which are intended to be exemplary only and do not limit the full scope of the present disclosure as set forth in the appended claims.

1. An ultraviolet (UV) radiation apparatus, comprising:
a chamber containing substrates;
a sample stage supporting the substrates, wherein the sample stage is positioned at a top of the chamber or a bottom of the chamber;
UV lamps emitting UV light, wherein the UV lamps are arranged opposite to the sample stage and are positioned at the top of the chamber or the bottom of the chamber;
a mirror reflective structure arranged in the chamber and reflecting the UV light emitted by the UV lamps;
wherein the mirror reflective structure comprises protrusions or recesses that are orderly arranged; the UV light is irradiated on the mirror reflective structure and the protrusions or the recesses reflect the UV light along all directions; the mirror reflective structure is arranged in a predetermined position of the chamber; the predetermined position of the chamber at least comprises one of four surfaces, the top and the bottom of the chamber.

2. The UV radiation apparatus as claimed in claim 1, wherein the protrusions or the recesses are distributed in an entire mirror reflective structure.

3. The UV radiation apparatus as claimed in claim 2, wherein the protrusions or the recesses are cone-shaped, pyramid-shaped, prismatic-shaped, tip-convex-shaped, or circular-convex-shaped.

4. The UV radiation apparatus as claimed in claim 1, wherein surfaces of the protrusions or the recesses are mirror surfaces.

5. The UV radiation apparatus as claimed in claim 1, wherein irradiating range of the UV lamps is greater than a region occupied by the sample stage.

6. The UV radiation apparatus as claimed in claim 1, wherein the chamber comprises at least two sample stages, and the at least two sample stages are positioned at same side of the top of the chamber or the bottom of the chamber to support at least one substrate.

7. The UV radiation apparatus as claimed in claim 1, wherein the UV radiation apparatus comprises at least two UV lamps, and the at least two UV lamps are symmetrically distributed at the top of the chamber.

8. The UV radiation apparatus as claimed in claim 1, wherein the UV lamps are the UV lamp panel, and the UV lamp panel covers an entire top or an entire bottom of the chamber.

9. The UV radiation apparatus as claimed in claim 1, wherein the sample stage that is raised or lowered to pick up and place the substrates.

10. An ultraviolet (UV) radiation apparatus, comprising:
a chamber containing substrates;
a sample stage supporting the substrates; wherein the sample stage is positioned at a top of the chamber or a bottom of the chamber;
UV lamps emitting UV light; wherein the UV lamps is arranged opposite to the sample stage and is positioned at the top of the chamber or the bottom of the chamber;
a mirror reflective structure arranged in the chamber and reflecting the UV light emitted by the UV lamps;
wherein the mirror reflective structure comprises protrusions or recesses that are orderly arranged; the protrusions or the recesses reflects the UV light along all directions and the UV light is irradiated on the mirror reflective structure.

11. The UV radiation apparatus as claimed in claim 10, wherein the protrusions or the recesses are distributed in entire mirror reflective structure.

12. The UV radiation apparatus as claimed in claim 11, wherein the protrusions or the recesses are cone-shaped, pyramid-shaped, prismatic-shaped, tip-convex-shaped, or circular-convex-shaped.

13. The UV radiation apparatus as claimed in claim 10, wherein surfaces of the protrusions or the recesses are mirror surfaces.

14. The UV radiation apparatus as claimed in claim 10, wherein irradiating range of the UV light is greater than a region occupied by the sample stage.

15. The UV radiation apparatus as claimed in claim 10, wherein the chamber comprises at least two sample stages, and the at least two sample stages are positioned at same side of the top of the chamber or the bottom of the chamber to support at least one substrate.

16. The UV radiation apparatus as claimed in claim 10, wherein the UV radiation apparatus comprises at least two UV lamps, and the at least two UV lamps are symmetrically distributed at the top of the chamber.

17. The UV radiation apparatus as claimed in claim 10, wherein the UV lamps are the UV lamp panel, and the UV lamp panel covers an entire top or an entire bottom of the chamber.

18. The UV radiation apparatus as claimed in claim 10, wherein the sample stage that is raised or lowered to pick up and place the substrates.
